(19) United States
(12) Patent Application Publication
(10) Pub. No.: US 2025/0378858 A1
(43) Pub. Date: Dec. 11, 2025

(54) SEMICONDUCTOR INTEGRATED CIRCUIT DEVICE

(71) Applicant: Socionext Inc., Kanagawa (JP)

(72) Inventor: Yasumitsu SAKAI, Yokohama-shi (JP)

(21) Appl. No.: 19/310,443

(22) Filed: Aug. 26, 2025

Related U.S. Application Data
(63) Continuation of application No. PCT/JP2023/008010, filed on Mar. 3, 2023.

(51) Int. Cl. G11C 5/14

(52) U.S. Cl. CPC G11C 5/14

(57) ABSTRACT

A semiconductor integrated circuit device includes: a driver circuit connected to a memory cell array via a word line; a clamp element provided between the word line and a ground potential; and a control circuit having a first circuit that turns ON/OFF the clamp element and a second circuit connected at its output to an input of the first circuit. A first power supply node supplying first power is connected to the first circuit, and a second power supply node connected to the first power supply node via a switch element is connected to the driver circuit and the second circuit.

### CROSS-REFERENCE TO RELATED APPLICATIONS

This is a continuation of International Application No. PCT/JP2023/008010 filed on Mar. 3, 2023. The entire disclosure of this application is incorporated by reference herein.

### BACKGROUND

The present disclosure relates to a semiconductor integrated circuit device.

To respond to requests for lower-power semiconductor integrated circuit devices, there is a technique of reducing leak currents of transistors occurring during sleep of a semiconductor memory device. There is also a technique of preventing corruption of data held in memory cells in a semiconductor memory device during sleep of the device.

For example, Japanese Unexamined Patent Publication No. 2006-179974 describes a semiconductor integrated circuit device having a plurality of MOS circuits connected in multiple stages so that an output signal of a preceding stage is supplied to its subsequent stage as an input signal. In this semiconductor integrated circuit device, a power shutoff circuit for MOS circuits at odd-numbered stages counted from the final stage is formed separately from that for MOS circuits at even-numbered stages, and the timing of power supply at the time of return from the sleep state to the active state is made different from each other. Also, during the sleep, word lines are driven to L level.

In the cited patent document, however, since power shutoff circuits are formed separately between MOS circuits at odd-numbered stages and MOS circuits at even-numbered stages, it is necessary to control the timing of shutoff operation, and this makes the design difficult. Also, since the scale of the control circuit for shutting off power increases, the area occupied by the circuit increases.

An objective of the present disclosure is simplifying the power shutoff control and facilitating the design of a control circuit for this control on the occasion of reducing leak currents of transistors during sleep while preventing corruption of data held in a memory cell array.

### SUMMARY

According to one mode of the disclosure, a semiconductor integrated circuit device includes: a driver circuit connected to a memory cell array via a word line; a clamp element provided between the word line and a ground potential; and a control circuit having a first circuit configured to turn ON/OFF the clamp element and a second circuit connected at its output to an input of the first circuit, wherein a first power supply node supplying first power is connected to the first circuit, and a second power supply node connected to the first power supply node via a switch element is connected to the driver circuit and the second circuit.

According to the above mode, since it is only necessary to shut off one spot, i.e., the switch element, in the power supply route to be shut off for reduction of leak currents of transistors during sleep, the shutoff control by the control circuit is simplified, and the design of the control circuit is facilitated. Also, since the first power is supplied to the first circuit even when the switch element is made OFF during sleep, the clamp element can be fixed to the conductive state. This can prevent corruption of data held in memory cells constituting the memory cell array during the sleep. Moreover, since the second circuit is provided at a preceding stage of the first circuit, at the time of sleep release, the clamp element is made nonconductive after the switch element has turned ON to operate the driver circuit. It is therefore possible to prevent corruption of data held in memory cells at the time of sleep release.

According to the present disclosure, on the occasion of reducing leak currents of transistors during sleep while preventing corruption of data held in memory cells, it is only necessary to shut off one spot in the power supply route to be shut off. This simplifies the shutoff control and facilitates the design of the control circuit. Moreover, the scale and occupied area of the control circuit can be reduced.

### BRIEF DESCRIPTION OF THE DRAWINGS

FIG. 1 is a functional block diagram showing a configuration example of a semiconductor integrated circuit device according to the first embodiment.

FIG. 2 is a view showing a circuit configuration example of a memory cell in FIG. 1.

FIG. 3 is a timing chart showing an operation example of the semiconductor integrated circuit device according to the first embodiment.

FIG. 4 is a functional block diagram showing a configuration example of a semiconductor integrated circuit device according to the second embodiment.

### DETAILED DESCRIPTION

Embodiments of the present disclosure will be described hereinafter with reference to the accompanying drawings. Note that a power supply node and a power supply voltage supplied to the power supply node may be described using the same reference character. Also, a signal line and a signal passing through the signal line may be described using the same reference character.

### First Embodiment

A semiconductor integrated circuit device 1 includes a memory cell array 2, a word line driver 3, and a control circuit 8. In other words, the semiconductor integrated circuit device 1 includes, as a semiconductor memory device, the memory cell array 2 and the word line driver 3.

### —Memory Cell Array—

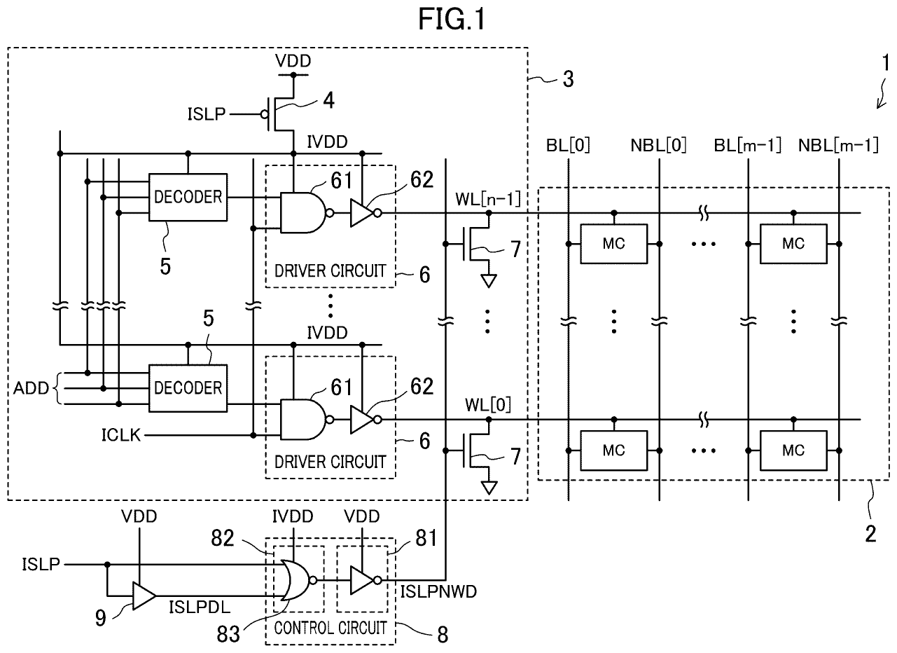

As shown in FIG. 1, the memory cell array 2 includes a plurality of memory cells MC arranged in an array of m columns (m is a natural number)×n rows (n is a natural number). In the memory cell array 2, provided are a plurality of (n in FIG. 1) word lines WL extending in the row direction and a plurality of (each m in FIG. 1) bit lines BL and NBL extending in the column direction. Each of the memory cells MC is connected to a corresponding word line WL[x] (x is an integer from 0 to n-1) and corresponding bit lines BL[y] and NBL[y] (y is an integer from 0 to m-1) according to the position of the memory cell MC.

Note that, when the plurality of word lines WL[x] are mentioned with no distinction among them, they may be referred to as the “word lines WL” simply. Also, when the plurality of bit lines BL[y] and NBL[y] are mentioned with no distinction among them, they may be referred to as the “bit lines BL and NBL” simply.

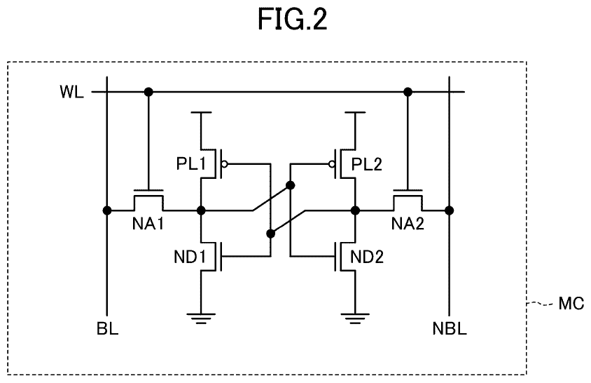

FIG. 2 is a circuit diagram showing an internal configuration of the memory cell MC in FIG. 1. In FIG. 2, the memory cell MC includes n-type transistors NA1 and NA2, p-type transistors PL1 and PL2, and n-type transistors ND1 and ND2.

In the n-type transistor NA1, the gate is connected to the word line WL and the source is connected to the bit line BL. In the n-type transistor NA2, the gate is connected to the word line WL and the source is connected to the bit line NBL. In the p-type transistor PL1, the power supply voltage VDD is supplied to the source, and the drain is connected to the drain of the n-type transistor NA1. In the n-type transistor ND1, the gate is connected to the gate of the p-type transistor PL1, the drain is connected to the drain of the p-type transistor PL1, and the source is connected to the ground potential VSS. In the p-type transistor PL2, the power supply voltage VDD is supplied to the source, and the drain is connected to the drain of the n-type transistor NA2. In the n-type transistor ND2, the gate is connected to the gate of the p-type transistor PL2, the drain is connected to the drain of the p-type transistor PL2, and the source is connected to the ground potential VSS. The connection node of the gate of the p-type transistor PL1 and the gate of the n-type transistor ND1 is connected to the drain of the n-type transistor NA2. The connection node of the gate of the p-type transistor PL2 and the gate of the n-type transistor ND2 is connected to the drain of the n-type transistor NA1.

In other words, the p-type transistor PL1 and the n-type transistor ND1 constitute a first inverter, and the p-type transistor PL2 and the n-type transistor ND2 constitute a second inverter. The input terminal of the first inverter is connected to the output terminal of the second inverter, and the output terminal of the first inverter is connected to the input terminal of the second inverter, whereby a latch is formed.

### —Word Line Driver—

Referring back to FIG. 1, the word line driver 3 includes a switch element 4 provided between a first power supply node VDD to which the power supply voltage VDD (corresponding to the first power supply voltage) is supplied and a second power supply node IVDD. The switch element 4 switches between conduction and non-conduction (ON and OFF) between the first power supply node VDD and the second power supply node IVDD based on an internal sleep signal ISLP.

FIG. 1 shows an example of the switch element 4 formed of a p-type transistor. In this case, the internal sleep signal ISLP is input into the gate of the switch element 4. The switch element 4 allows conduction between the first power supply node VDD and the second power supply node IVDD when the internal sleep signal ISLP is ‘L’, and blocks conduction between the first power supply node VDD and the second power supply node IVDD when the internal sleep signal ISLP is ‘H’. Note that the switch element 4 is not limited to the p-type transistor, but may be formed using any other element or circuit having the function of switching between conduction and non-conduction between the first power supply node VDD and the second power supply node IVDD.

The word line driver 3 also includes a decoder 5, a driver circuit 6, and a clamp element 7 provided for each of the word lines WL. In the example of FIG. 1, for the n word lines, n decoders 5, n driver circuits 6, and n clamp element 7 are provided.

The decoder 5 decodes an internal address signal ADD and outputs the decoded signal to the driver circuit 6. The decoder 5 is connected to the second power supply node IVDD and supplied with the power supply voltage VDD via the switch element 4.

The driver circuit 6 receives the output of the decoder 5 and an internal clock ICLK as inputs and activates the word line WL corresponding to the internal address signal ADD. The driver circuit 6 is connected to the second power supply node IVDD and supplied with the power supply voltage VDD via the switch element 4.

In the example of FIG. 1, the driver circuit 6 is constituted by a 2-input NAND circuit 61 receiving the output of the decoder 5 and the internal clock ICLK as the inputs and an inverter 62 provided between the output of the NAND circuit 61 and the word line WL. Note that the driver circuit 6 is not limited to the configuration in FIG. 1, but may be any other circuit having a similar function.

The clamp element 7 is provided between the word line WL and the ground potential VSS. The clamp element 7 switches between conduction and non-conduction between the word line WL and the ground potential VSS based on a control signal ISLPNWD output from the control circuit 8.

FIG. 1 shows an example of the clamp element 7 formed of an n-type transistor provided between the word line WL and the ground potential VSS. The gate of this n-type transistor is connected to the output node ISLPNWD of the control circuit 8. Note that the clamp element 7 is not limited to the n-type transistor, but may be formed using any other element or circuit having the function of switching between conduction and non-conduction between the word line WL and the ground potential VSS.

The control circuit 8 is a circuit that controls conduction/non-conduction of the clamp element 7. The control circuit 8 includes a first circuit 81 of which the output node ISLPNWD is connected to the clamp element 7 and a second circuit 82 of which the output is connected to the input of the first circuit 81.

The second circuit 82 outputs a delayed signal of the internal sleep signal ISLP to the first circuit 81. The second circuit 82 is connected to the second power supply node IVDD and supplied with the power supply voltage VDD via the switch element 4.

FIG. 1 shows an example of the second circuit 82 formed of a 2-input NOR circuit 83. The internal sleep signal ISLP is connected to one of the inputs of the NOR circuit 83, and an internal sleep delayed signal ISLPDL obtained by delaying the internal sleep signal ISLP by a buffer 9 and wiring (not shown) is connected to the other input. The buffer 9 is connected to the first power supply node VDD and supplied with the power supply voltage VDD from the first power supply node VDD.

The output of the NOR circuit 83 is connected to the input of the first circuit 81, whereby a signal delayed from the internal sleep signal ISLP is output from the second circuit 82 to the first circuit 81.

The first circuit 81 receives the output signal of the second circuit 82 as the input signal, and makes the clamp element 7 nonconductive during normal operation and conductive during sleep. The first circuit 81 is connected to the first power supply node VDD and supplied with the power supply voltage VDD from the first power supply node VDD.

FIG. 1 shows an example of the first circuit 81 formed of an inverter. The output node of the second circuit 82 is connected to the input node of the inverter, and the output node ISLPNWD of the inverter is connected to each clamp 7. In the example of FIG. 1, the output node ISLPNWD of the first circuit 81 is connected to the gate of the transistor constituting each clamp element 7.

### —Operation of Semiconductor Integrated Circuit Device—

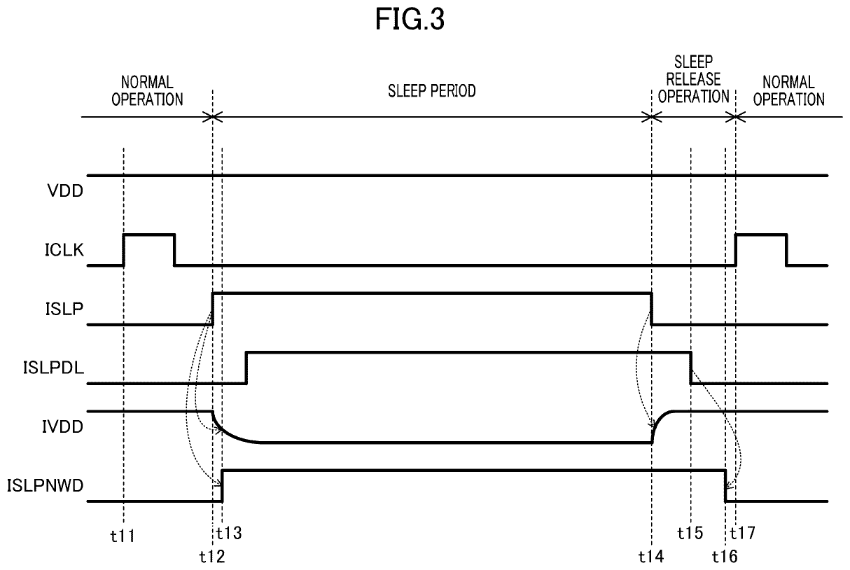

Next, referring to FIG. 3, the operation of the semiconductor integrated circuit device 1 will be described. In this example, normal operation is performed when the internal sleep signal ISLP is ‘L’, and the state shifts to the sleep state when the internal sleep signal ISLP becomes ‘H’ from ‘L’.

### (Normal Operation)

First, the normal operation will be described.

As shown in FIG. 3, during the normal operation, since the internal sleep signal ISLP is ‘L’, the switch element 4 is ON, allowing conduction between the first power supply node VDD and the second power supply node IVDD. That is, to the second power supply node IVDD, the same power supply voltage VDD as that at the first power supply node VDD is supplied.

Also, during the normal operation, since both the internal sleep signal ISLP and the internal sleep delayed signal ISLPDL are ‘L’ and this makes the output of the second circuit 82 ‘H’, the control circuit 8 (first circuit 81) outputs ‘L’ as the control signal ISLPNWD. With this, the clamp elements 7 connected to the word lines WL are OFF and nonconductive.

At time t11, when the internal clock ICLK becomes ‘H’, the word line WL corresponding to the internal address signal ADD becomes ‘H’, and read/write access to a memory cell MC connected to this word line WL is executed.

### (Operation During Sleep Period)

Next, the operation during the sleep period (period during which the internal sleep signal is ‘H’) including shift operation to the sleep state will be described.

At time t12, when the internal sleep signal ISLP becomes ‘H’ from ‘L’, the switch element 4 turns OFF, becoming nonconductive. This stops the supply of the power supply voltage VDD to the second power supply node IVDD, i.e., the supply of the internal power supply IVDD, whereby the voltage of the second power supply node IVDD mildly falls.

Also, after the lapse of a predetermined delay time from the shift of the internal sleep signal ISLP from ‘L’ to ‘H’, the output of the second circuit 82 becomes ‘L’ from ‘H’, and therefore the control signal ISLPNWD becomes ‘H’ from ‘L’ (see time t13). With this, the clamp elements 7 connected to the word lines WL are turned ON, becoming conductive, whereby the word lines WL are fixed to ‘L’.

Since the first circuit 81 is supplied with power from the first power supply node VDD, it outputs ‘H’ as the control signal ISLPNWD, independent of the second power supply node IVDD, during the sleep period (see time t13 to time t14). That is, the state where the word lines WL are ‘L’ is held. Also, since the internal clock ICLK is held at ‘L’ until the next start of the normal operation, and also power supply to the driver circuits 6 is stopped, the driver circuits 6 maintain the stop state.

As a result of the above, leak currents of transistors constituting the driver circuits 6 are reduced. Also, since the transistors of the driver circuits 6 are prevented from performing unnecessary switching operation, it is possible to prevent an occurrence of through currents between the power supplies or an occurrence of ringing noise to the word lines WL.

### (Sleep Release Operation)

Next, the operation of releasing the sleep will be described.

At time t14, when the internal sleep signal ISLP becomes ‘L’ from ‘H’ to release the sleep, the switch element 4 turns ON, allowing conduction between the first power supply node VDD and the second power supply node IVDD. That is, to the second power supply node IVDD, the same power supply voltage VDD as that at the first power supply node VDD is supplied, whereby the internal power supply IVDD rises.

With the above, the decoders 5 and the driver circuits 6 are supplied with the power supply voltage VDD, thereby resuming the same operation states as those during the normal operation. At this time, since the internal clock ICLK is ‘L’, the driver circuits 6 immediately output ‘L’.

Also, when the internal sleep signal ISLP becomes ‘L’ from ‘H’, one input signal of the second circuit 82 immediately falls from ‘H’ to ‘L’ in response to this change. On the other hand, the internal sleep delayed signal ISLPDL input into the other input of the second circuit 82 falls from ‘H’ to ‘L’ delaying by a time required to pass through the buffer 9 and wiring (see time t15). As a result, the control signal ISLPNWD is to fall from ‘H’ to ‘L’ (see time t16) after the internal sleep signal ISLP has become ‘L’ from ‘H’ raising the internal power supply IVDD, then the internal sleep delayed signal ISLPDL has become ‘L’ from ‘H’, and furthermore a fixed delay time has passed. Once the control signal ISLPNWD becomes ‘L’ from ‘H’, the clamp elements 7 turn OFF from ON, becoming nonconductive, and resume the normal operation state. That is, the clamp elements 7 are configured to become nonconductive after the internal power supply IVDD has risen and the word lines WL have shifted to ‘L’ by the driver circuits 6.

Thereafter, at time t17, when the internal clock ICLK becomes ‘H’, the word line WL corresponding to the internal address signal ADD becomes ‘H’, and read/write access to a memory cell MC connected to the word line WL is executed.

As described above, according to this embodiment, since it is only necessary to shut off one spot, i.e., the switch element 4, in the power supply route to be shut off during sleep for reduction of leak currents of transistors in the word line driver 3, the shutoff control by the control circuit 8 is simplified, and the design of the control circuit 8 is facilitated.

Also, according to this embodiment, the word lines WL can hold the ‘L’ state during sleep. At the time of sleep release, the clamp elements 7 are configured to become nonconductive after the internal power supply IVDD has risen and the word lines WL has shifted to ‘L’ by the driver circuits 6. This makes it possible to prevent corruption of data held in memory cells constituting the memory cell array during the sleep period and at the time of sleep release. Moreover, since the driver circuits 6 are prevented from performing unnecessary switching operation during the sleep, neither through currents between the power supplies nor ringing noise to the word lines WL will occur.

### Second Embodiment

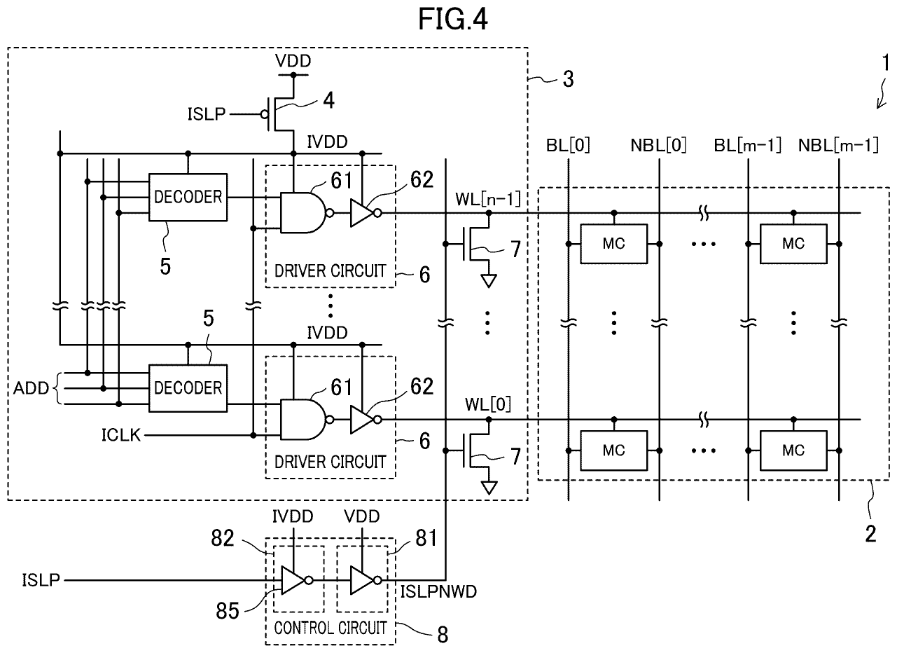

Referring to FIG. 4, a semiconductor integrated circuit device 1 according to the second embodiment will be described. Description here will be made centering on differences from the first embodiment, and duplicate description may be omitted.

In this embodiment, in comparison with the first embodiment, the configuration of the control circuit 8 and its peripheral circuits is different.

Specifically, in this embodiment, the second circuit 82 is constituted by an inverter 85 provided between the internal sleep signal ISLP and the input of the first circuit 81. The inverter 85 is set so that its input/output delay amount is in the same degree as the delay amount obtained by the buffer 9, the wiring (not shown), and the NOR circuit 83 described in the first embodiment. Therefore, as in the first embodiment, a signal delayed from the internal sleep signal ISLP is output from the second circuit 82 to the first circuit 81. As a result, the control signal ISLPNWD falls from ‘H’ to ‘L’ after the lapse of a fixed delay time from the shift of the internal sleep signal ISLP from ‘H’ to ‘L’.

Thus, in this embodiment, also, an operation similar to the “Operation of Semiconductor Integrated Circuit Device” described in the first embodiment can be achieved, and effects similar to those in the first embodiment can be obtained. Also, in this embodiment, in comparison with the first embodiment, the configuration of the control circuit can be simplified.

According to the present disclosure, in a semiconductor integrated circuit device, leak currents of transistors during sleep can be reduced while corruption of data held in a memory cell array is prevented. Moreover, the power shutoff control can be simplified, and the design of the control circuit for this control can be facilitated. The present disclosure is therefore very useful.

1. A semiconductor integrated circuit device, comprising:
a driver circuit connected to a memory cell array via a word line;
a clamp element provided between the word line and a ground potential; and
a control circuit includes a first circuit configured to turn ON/OFF the clamp element and a second circuit connected at its output to an input of the first circuit,
wherein
a first power supply node supplying first power is connected to the first circuit, and
a second power supply node connected to the first power supply node via a switch element is connected to the driver circuit and the second circuit.

2. The semiconductor integrated circuit device of claim 1, wherein
the second circuit includes a delay circuit configured to delay an input signal to the second circuit.
